(19) United States
(12) Patent Application Publication
(10) Pub. No.: US 2025/0248131 A1
(43) Pub. Date: Jul. 31, 2025

(54) SEMICONDUCTOR DEVICE

(71) Applicant: Renesas Electronics Corporation, Tokyo (JP)

(72) Inventor: Koki NARITA, Tokyo (JP)

(21) Appl. No.: 18/931,208

(22) Filed: Oct. 30, 2024

(30) Foreign Application Priority Data
Jan. 31, 2024 (JP) 2024-013502

(51) Int. Cl. H01L 27/02

(52) U.S. Cl. CPC H10D 89/819; H10D 89/931

(57) ABSTRACT

Improve the reliability of semiconductor device. The protective cell ESD1a comprises a group of MISFETS 1QA constituted by a plurality of n-type MISFETs 1Q, and a pair of MISFET groups 2QA constituted by a plurality of p-type MISFETs 2Q. The group of MISFETs 1QA and the pair of MISFET groups 2QA are electrically connected to the power wiring and the ground wiring, respectively, to electrically short-circuit them. The pair of MISFET groups 2QA outputs a signal to turn on a plurality of MISFETs 10 to each gate electrode of the plurality of MISFETs 1Q. The group of MISFETs 1QA is provided between the pair of MISFET groups 2QA.

### CROSS-REFERENCE TO RELATED APPLICATIONS

The disclosure of Japanese Patent Application No. 2024-013502 filed on Jan. 31, 2024, including the specification, drawings and abstract is incorporated herein by reference in its entirety.

### BACKGROUND

The present invention relates to a semiconductor device, and more particularly, to a semiconductor device equipped with a protection cell for an ESD (Electro-Static Discharge) protection circuit.

The semiconductor device equipped with ESD protection circuits are used to protect various circuits formed within the semiconductor device from destruction by static electricity. An ESD protection circuit, for example, comprises a detection circuit, an inverter, and a discharge circuit. When the detection circuit detects an ESD current to the power supply wiring, the detection circuit outputs a detection signal to the inverter. The inverter, in response to the detection signal, outputs a drive signal to the gate electrodes of a plurality of MISFETs (Metal Insulator Semiconductor Field Effect Transistors) constituting the discharge circuit. By turning on each MISFET in the discharge circuit, the ESD current is discharged from the power supply wiring to the ground wiring.

There are disclosed techniques listed below.
[Patent Document 1] International Publication No. 2016/203648

For example, Patent Document 1 discloses an ESD protection circuit having an RC timer as a detection circuit, an inverter, and an n-channel transistor as a discharge circuit. Furthermore, in Patent Document 1, the planar layout of the ESD protection circuit is disclosed, where the RC timer, the inverter, and the n-channel transistor are arranged in sequence along one direction.

### SUMMARY

With the miniaturization of the semiconductor device, the thinning and narrowing of wiring are progressing. In the wiring connecting the gate electrodes of each MISFET constituting the inverter and the discharge circuit, the resistance of the wiring is increasing due to the thinning and narrowing of the wiring. Moreover, with the miniaturization of the semiconductor device, the thinning of the gate insulating film of MISFETS is progressing, and the gate capacitance of MISFETs is increasing.

With the increase in wiring resistance and gate capacitance, RC delay of the drive signal occurs, leading to a problem where the driving force of the gate in some of the plurality of MISFETs in the discharge circuit is reduced, and the speed at which they turn on becomes slower. That is, as the clamp performance of the ESD protection circuit deteriorates, the ESD withstand voltage also decreases. As a result, there is a problem of reduced reliability of the semiconductor device.

Other issues and novel features will become apparent from the description of this specification and the accompanying drawings.

The typical ones of the embodiments disclosed in the present application will be briefly described as follows.

In one embodiment, the semiconductor device comprises a protection cell, a power supply wiring for supplying a power potential, and a ground wiring for supplying a ground potential. The protective cell comprises a first MISFET group and a pair of second MISFET groups, wherein the first MISFET group and the pair of the second MISFET groups are electrically connected to the power supply wiring and the ground wiring, respectively, so as to electrically short-circuit the power supply wiring and the ground wiring. The pair of the second MISFET groups outputs a signal to turn on the plurality of first MISFETs included in the first MISFET group to each of the first gate electrodes of the plurality of first MISFETs, and the first MISFET group is provided between the pair of the second MISFET groups.

In one embodiment, the semiconductor device comprises an analog IP, a protective cell provided adjacent to the analog IP, a power supply wiring for supplying a power potential to the analog IP, and a ground wiring for supplying a ground potential to the analog IP. The protective cell comprises a first MISFET group and a pair of second MISFET groups, wherein the first MISFET group and the pair of the second MISFET groups are electrically connected to the power supply wiring and the ground wiring, respectively, so as to electrically short-circuit the power supply wiring and the ground wiring. The pair of the second MISFET groups outputs a signal to turn on the plurality of first MISFETs included in the first MISFET group to each of the first gate electrodes of the plurality of first MISFETs, and the first MISFET group is provided between the pair of the second MISFET groups.

According to one embodiment, the reliability of the semiconductor device can be improved.

### BRIEF DESCRIPTION OF THE DRAWINGS

FIG. 1 is a plan view showing a semiconductor device according to a first embodiment.

FIG. 2 is a plan view showing a semiconductor device according to a first embodiment.

FIG. 3 is an equivalent circuit diagram showing an ESD protection circuit according to a first embodiment and an examined example.

FIG. 4 is an equivalent circuit diagram showing an ESD protection circuit according to a first embodiment.

FIG. 5 is an equivalent circuit diagram showing an ESD protection circuit according to an examined example.

FIG. 6 is a plan view showing a protection cell according to an examined example.

FIG. 7 is a plan view showing a protection cell according to a first embodiment.

FIG. 8 is a plan view showing power supply wiring and ground wiring formed above a protection cell according to a first embodiment.

FIG. 9 is a plan view showing a plurality of wirings formed above a protection cell according to a first embodiment.

FIG. 10 is a plan view showing power supply wiring and ground wiring formed above a protection cell according to a first embodiment.

FIG. 11 is a plan view showing a protection cell according to a first embodiment.

FIG. 12 is a plan view showing power supply wiring and ground wiring formed above a protection cell according to a first embodiment.

FIG. 13 is a plan view showing power supply wiring and ground wiring formed above a protection cell according to a first embodiment.

FIG. 14 is a cross-sectional view showing a protection cell according to a first embodiment.

FIG. 15 is a plan view showing power supply wiring and ground wiring formed above a protection cell according to a first embodiment.

FIG. 16 is a cross-sectional view showing power supply wiring and ground wiring according to a first embodiment.

FIG. 17 is a plan view showing a MISFET according to a first embodiment.

FIG. 18 is a cross-sectional view showing a MISFET according to a first embodiment.

FIG. 19 is a plan view showing a protection cell and an analog IP according to a second embodiment.

FIG. 20 is a plan view showing power supply wiring and ground wiring formed above a protection cell and an analog IP according to a second embodiment.

### DETAILED DESCRIPTION

Hereinafter, embodiments are described in detail with reference to the drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

Furthermore, the X direction, Y direction, and Z direction described in this application intersect each other and are orthogonal to each other. In this application, the Z direction is described as the vertical direction, depth direction, or thickness direction of a certain structure. The expressions “plan view” or “planar view” used in this application mean that the plane constituted by the X direction and Y direction is regarded as the “plane,” and viewing this “plane” from the Z direction.

### First Embodiment

### Semiconductor Device Plan Layout

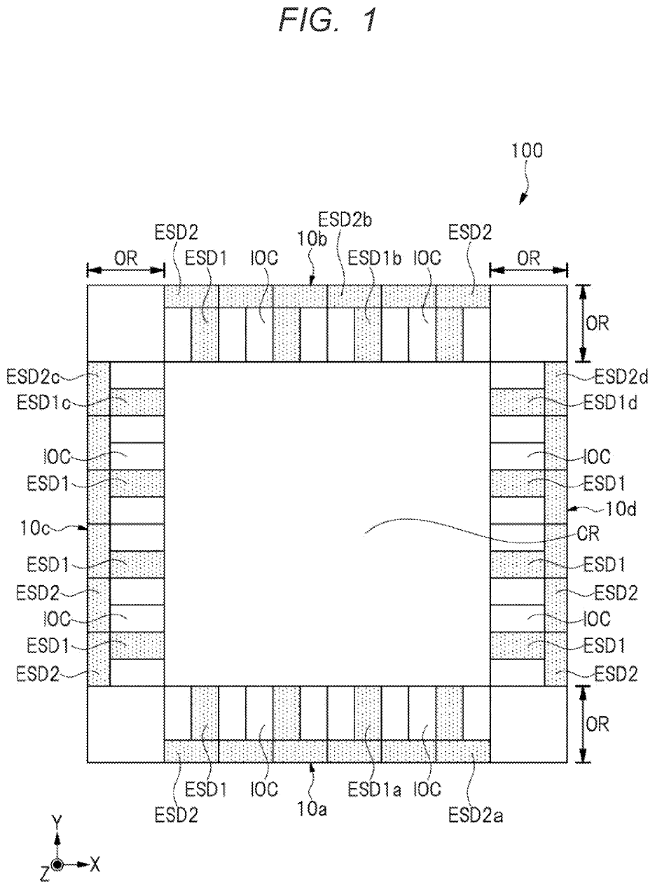

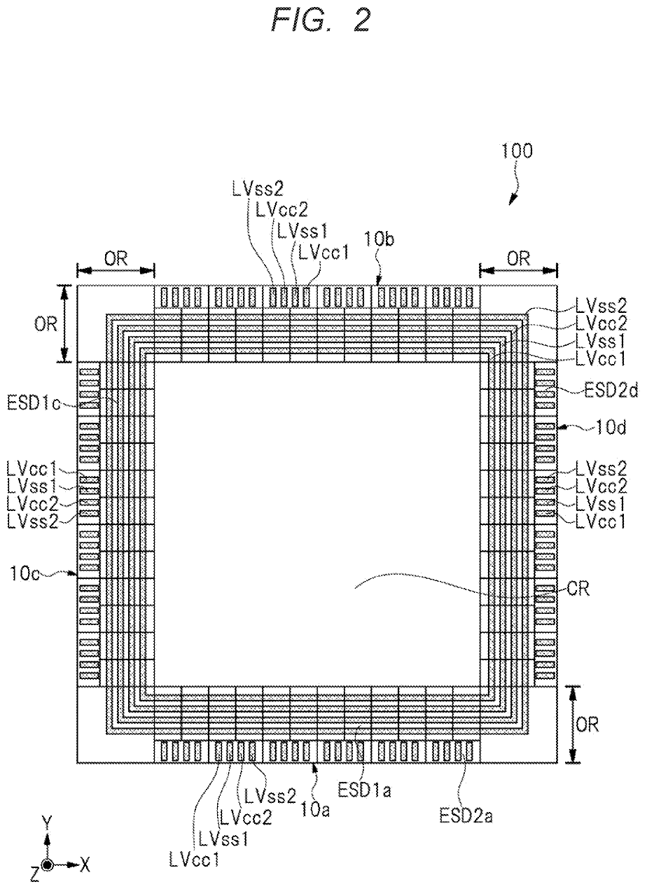

Hereinafter, the plan layout of the semiconductor device 100 in the first embodiment will be described with reference to FIGS. 1 and 2.

As shown in FIG. 1, the semiconductor device 100 is a semiconductor chip, comprising a core area CR and a peripheral area OR that surrounds the core area CR in a plan view. The core area CR is provided with a plurality of circuits. The plurality of circuits include, for example, logic circuits constituting a CPU or SRAM, analog IP (Intellectual Property), and non-volatile memory cells. IP refers to a circuit function block with a specific role. Examples of analog IP include PLL (Phase Locked Loop), TRNG (True Random Number Generator), oscillators, temperature sensors, Analog-to-Digital converters, and Digital-to-Analog converters.

The peripheral area OR is provided with a plurality of protection cells ESD1, a plurality of protection cells ESD2, and a plurality of I/O (Input/Output) signal cells IOC. The plurality of protection cells ESD1 and the plurality of protection cells ESD2 each include a plurality of MISFETs for constituting ESD protection circuits. The protection cells ESD1 constitute ESD protection circuits for the plurality of circuits provided in the core area CR. The protection cells ESD2 constitute ESD protection circuits for the I/O signal cells IOC.

The plan shape of the semiconductor device 100 is rectangular, and the semiconductor device 100 includes sides 10a and 10b along the X direction, and sides 10c and 10d along the Y direction. Sides 10a, 10b, 10c, and 10d constitute the outer edge of the peripheral area OR. The peripheral area OR is the area provided between the core area CR and sides 10a, 10b, 10c, and 10d. The protection cells ESD2 are provided between the protection cells ESD1 or I/O signal cells IOC and sides 10a, 10b, 10c, and 10d.

As shown in FIG. 2, the peripheral area OR is provided with a plurality of power supply wirings such as power supply wiring LVcc1 and LVcc2, and a plurality of ground wirings such as ground wiring LVss1 and LVss2. Power supply wiring LVcc1, power supply wiring LVcc2, ground wiring LVss1, and ground wiring LVss2 are provided so as to surround the core region CR in a plan view and to overlap with the protection cell ESD1 or protection cell ESD2 in a plan view.

The power supply wiring LVcc1 supplies a power potential to a plurality of circuits provided in the core region CR. The ground wiring LVss1 supplies a ground potential to a plurality of circuits provided in the core region CR. The power supply wiring LVcc2 supplies a power potential to the I/O signal cell IOC. The power potential supplied by the power supply wiring LVcc2 is higher than the power potential supplied by the power supply wiring LVcc1. The ground wiring LVss2 supplies a ground potential to the I/O signal cell IOC.

It should be noted that the power supply wiring LVcc1, power supply wiring LVcc2, ground wiring LVss1, and ground wiring LVss2 are each a wiring M13 formed in the global wiring layer among the multilayer wiring layers.

Furthermore, in the peripheral region OR, there exist power supply wiring LVcc1, power supply wiring LVcc2, ground wiring LVss1, and ground wiring LVss2 that circulate above a plurality of protection cells ESD1 and a plurality of I/O signal cells IOC, and power supply wiring LVcc1, power supply wiring LVcc2, ground wiring LVss1, and ground wiring LVss2 that are provided respectively above a plurality of protection cells ESD2. These wirings are electrically connected to each other by, for example, a wiring M14 formed in the wiring layer above the wiring M13.

### ESD Protection Circuit

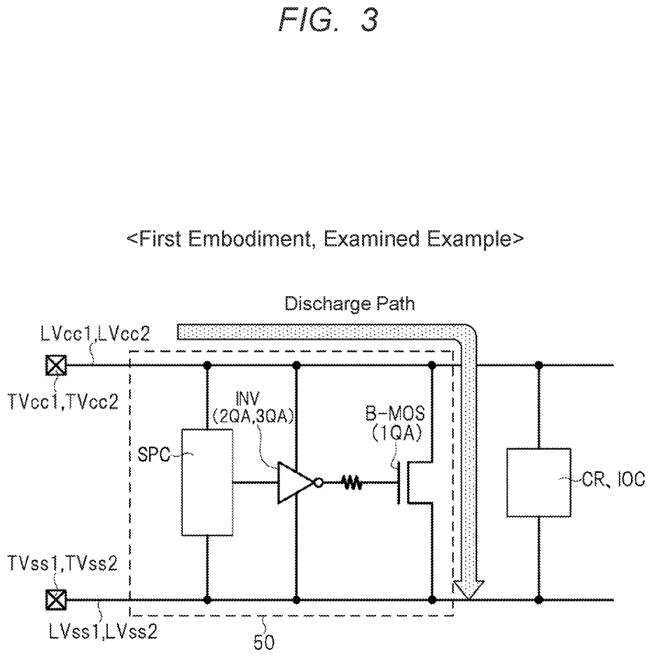

Hereinafter, the ESD protection circuit 50 provided in the semiconductor device 100 in the first embodiment will be described using FIG. 3.

As shown in FIG. 3, the plurality of circuits in the core region CR are supplied with a power potential from a power terminal TVcc1 connected to the power supply wiring LVcc1, and a ground potential from a ground terminal TVss1 connected to the ground wiring LVss1. The I/O signal cell IOC is supplied with a power potential from a power terminal TVcc2 connected to the power supply wiring LVcc2, and a ground potential from a ground terminal TVss2 connected to the ground wiring LVss2.

The ESD protection circuit 50 includes a detection circuit SPC, an inverter INV, and a discharge circuit B-MOS. The discharge circuit B-MOS includes a group of MISFETS 1QA constituted by a plurality of n-type MISFETs 1Q. The inverter INV includes a group of MISFETs 2QA constituted by a plurality of p-type MISFETs 2Q, and a group of MISFETs 3QA constituted by a plurality of n-type MISFETs 3Q. The detection circuit SPC is a time constant circuit that detects a positive surge voltage, and is constituted by, for example, an integration circuit including a resistive element and a capacitive element.

The detection circuit SPC for the protection cell ESD1, the inverter INV (groups of MISFETs 2QA, MISFETs 3QA), and the discharge circuit B-MOS (group of MISFETs 1QA) are electrically connected to the power supply wiring LVcc1 and the ground wiring LVss1 so as to electrically short-circuit them, respectively.

Detection circuit SPC for protection cell ESD2, inverter INV, and discharge circuit B-MOS are electrically connected to power wiring LVcc2 and ground wiring LVss2, respectively, so as to electrically short-circuit power wiring LVcc2 and ground wiring LVss2.

When the detection circuit SPC detects an ESD current to power wiring LVcc1 or power wiring LVcc2, the detection circuit SPC outputs a detection signal to the inverter INV. The MISFET group 2QA of the inverter INV, in response to the detection signal, outputs a signal to each gate electrode of the plurality of MISFETs 1Q constituting the discharge circuit B-MOS, to turn on the plurality of MISFETs 1Q. As a result, as shown in the “discharge path” of FIG. 3, the ESD current is discharged from power wiring LVcc1 or power wiring LVcc2 to ground wiring LVss1 or ground wiring LVss2.

If the detection circuit SPC does not detect an ESD current, the MISFET group 3QA of the inverter INV outputs a signal to each gate electrode of the plurality of MISFETs 1Q, to turn off the plurality of MISFETs 1Q.

For example, if a steep high voltage is applied to power terminal TVcc1 or power terminal TVcc2, the ESD current flows from power wiring LVcc1 or power wiring LVcc2 to ground wiring LVss1 or ground wiring LVss2 through the ESD protection circuit 50. This prevents circuits in the core area CR and protected circuits such as I/O signal cells IOC from being destroyed by the steep high voltage.

### Examined Example and its Problems

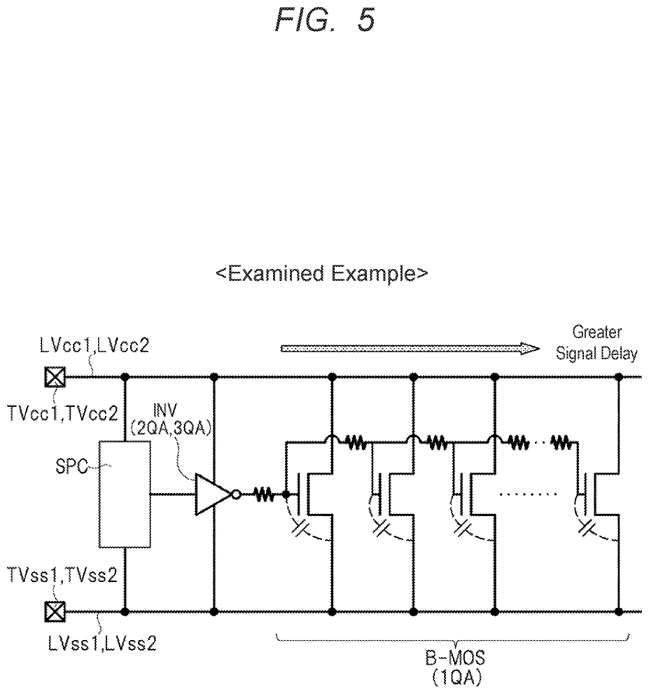

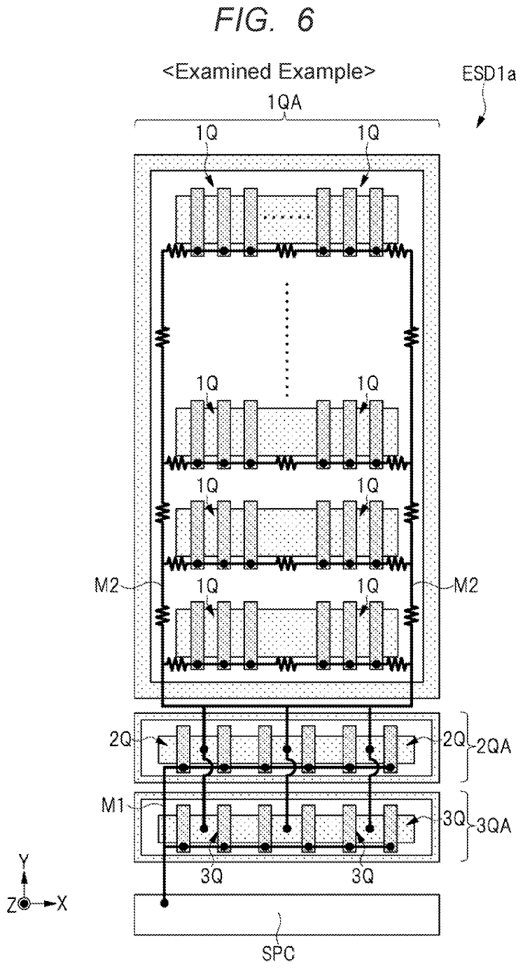

Hereinafter, a semiconductor device of an examined example, which the inventors of the present application have studied, will be described using FIGS. 5 and 6. FIG. 5 shows details of the discharge circuit B-MOS of FIG. 3. FIG. 6 shows a plan layout of the protection cell ESD1a for constituting the ESD protection circuit 50. The protection cell ESD1a is one of the plurality of protection cells ESD1 shown in FIG. 1, arranged along edge 10a.

As shown in FIGS. 5 and 6, the MISFET group 1QA consists of a plurality of MISFETs 1Q connected in parallel. As shown in FIG. 6, in the direction from the core area CR towards edge 10a, the MISFET groups 1QA, 2QA, 3QA, and the detection circuit SPC are provided in sequence.

The detection circuit SPC is electrically connected to each gate electrode of the plurality of MISFETs 2Q and the plurality of MISFETs 3Q via wiring M1 and wiring M2. Each drain region of the plurality of MISFETs 2Q and the plurality of MISFETs 3Q is electrically connected to each gate electrode of the plurality of MISFETs 1Q via wiring M1 and wiring M2. The wiring M1 is formed in the lowest wiring layer among the multilayer wiring layers, and the wiring M2 is formed in the wiring layer above the wiring M1.

In recent years, with the miniaturization of the semiconductor device, the thinning and narrowing of wirings have been progressing. In wiring such as wiring M1 and wiring M2 formed in a wiring layer close to MISFET, it is necessary to thin and narrow the film in order to cope with the miniaturization of MISFET, resulting in an increase in wiring resistance.

As described above, at the time of discharging ESD current, the MISFET group 2QA outputs a signal to each gate electrode of a plurality of MISFET1Qs to turn on a plurality of MISFET1Qs. However, as the thinning and narrowing of wiring M1 and wiring M2 progress, the increase in wiring resistance makes it more likely to occur RC delay of the output signal from MISFET group 2QA. The farther the distance from MISFET group 2QA, the greater the addition of wiring resistance, resulting in greater signal delay.

That is, among a plurality of MISFET1Qs, in MISFET1Qs that are far from MISFET group 2QA, the driving force of the gate decreases, or the speed of turning on becomes slower. Thus, it becomes difficult to sufficiently protect a plurality of circuits provided in the core region CR from ESD current, resulting in a problem of reduced reliability of the semiconductor device 100. Note that the same problem occurs not only with protection cell ESD1 but also with protection cell ESD2, making it difficult to sufficiently protect the I/O signal cell IOC.

### Protection Cell of the First Embodiment

Hereinafter, protection cells ESD1 and ESD2 in the first embodiment will be described using FIGS. 1, 4, 7 to 18.

A plurality of protection cells ESD1 shown in FIG. 1 include protection cell ESD1a arranged alongside 10a, protection cell ESD1b arranged alongside 10b, protection cell ESD1c arranged alongside 10c, and protection cell ESD1d arranged alongside 10d. A plurality of protection cells ESD2 shown in FIG. 1 include protection cell ESD2a arranged alongside 10a, protection cell ESD2b arranged alongside 10b, protection cell ESD2c arranged alongside 10c, and protection cell ESD2d arranged alongside 10d.

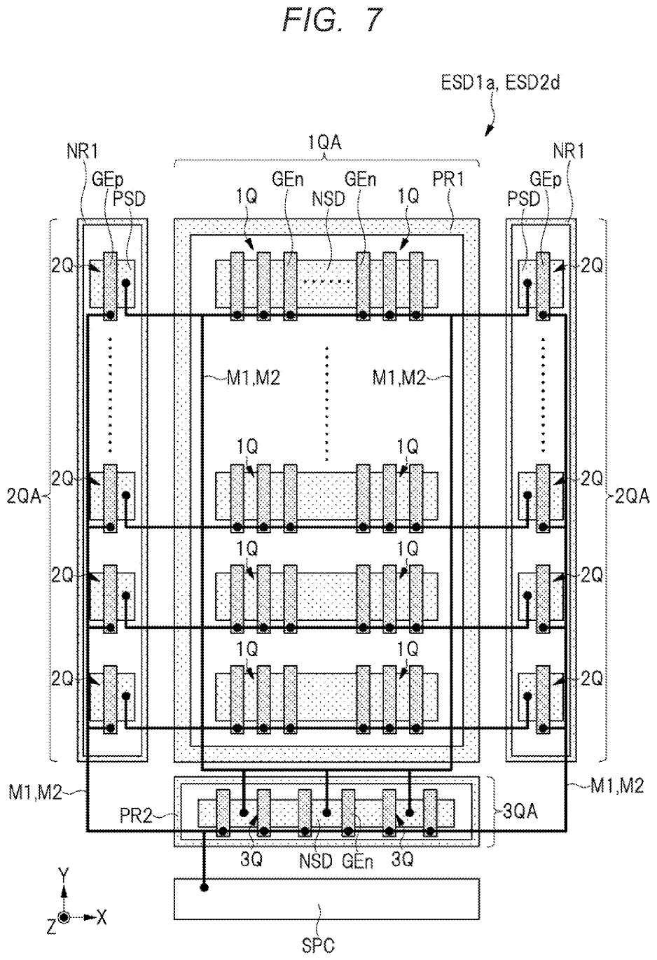

FIG. 7 shows the plan layout of protection cell ESD1a and protection cell ESD2d. The plan layout of protection cell ESD1b is similar to the plan layout of protection cell ESD1a rotated 180 degrees in plain view. The plan layout of protection cell ESD2c is similar to the plan layout of protection cell ESD2d rotated 180 degrees in plain view.

Moreover, the plan layout of protection cell ESD2 is the same as the plan layout of protection cell ESD1. However, the thickness of the gate insulating film of each MISFET provided in protection cell ESD2 is thicker than the thickness of the gate insulating film of each MISFET provided in protection cell ESD1.

As shown in FIG. 7, in the first embodiment, the location where the MISFET group 2QA is provided differs from the examined example. In the first embodiment, the protection cells ESD1a and ESD2d have a pair of MISFET groups 2QA. The MISFET group 1QA is adjacent to a pair of MISFET groups 2QA and is provided between the pair of MISFET groups 2QA.

Furthermore, in the direction from the core region CR towards the edge 10a, the MISFET group 1QA, the MISFET group 3QA, and the detection circuit SPC are provided in sequence. In other words, the MISFET group 1QA is provided between the core region CR and the MISFET group 3QA. The MISFET group 3QA is provided between the MISFET group 1QA and the detection circuit SPC.

Moreover, the arrangement shape of the MISFET group 1QA in plain view forms a rectangular shape. The pair of MISFET groups 2QA is provided along the long side of the MISFET group 1QA, and the MISFET group 3QA is provided along the short side of the MISFET group 1QA. The detection circuit SPC is provided along the short side of the MISFET group 1QA through the MISFET group 3QA.

The MISFET1Q has an n-type gate electrode GEn formed on a semiconductor substrate through a gate insulating film, and an n-type impurity region NSD formed in the semiconductor substrate. The impurity region NSD constitutes the source region or drain region of the MISFET1Q. In the semiconductor substrate, a p-type impurity region PR1 is formed. The impurity region PRI surrounds a plurality of MISFET1Qs in plain view. The MISFET group 1QA consists of a plurality of MISFET1Qs connected in parallel.

The MISFET2Q has a p-type gate electrode GEp formed on a semiconductor substrate through a gate insulating film, and a p-type impurity region PSD formed in the semiconductor substrate. The impurity region PSD constitutes the source region or drain region of the MISFET2Q. In the semiconductor substrate, an n-type impurity region NR1 is formed. The impurity region NR1 surrounds a plurality of MISFET2Qs in plain view. The MISFET group 2QA consists of a plurality of MISFET2Qs connected in parallel.

The MISFET3Q has an n-type gate electrode GEn formed on a semiconductor substrate through a gate insulating film, and an n-type impurity region NSD formed in the semiconductor substrate. The impurity region NSD constitutes the source region or drain region of the MISFET3Q. In the semiconductor substrate, a p-type impurity region PR2 is formed. The impurity region PR2 surrounds a plurality of MISFET3Qs in plain view. The MISFET group 3QA consists of a plurality of MISFET3Qs connected in parallel.

It should be noted that, in the first embodiment, the case where the MISFET1Q is of n-type, the MISFET2Q is of p-type, and the MISFET3Q is of n-type is exemplified. However, in the case where the MISFET1Q is of p-type, p-type MISFET2Q and n-type MISFET3Q are used. In that case, for example, the impurity region NSD becomes a p-type impurity region, and the conductivity type of each component included in the MISFET groups 1QA, 2QA, and 3QA becomes the opposite conductivity type.

In order to connect MISFET group 1QA, MISFET group 2QA, MISFET group 3QA, and detection circuit SPC, a plurality of wirings M1 and a plurality of wirings M2 are used. The wiring M1 is formed in the wiring layer at the lowest layer among the multilayer wiring layers, and the wiring M2 is formed in the wiring layer one layer above the wiring M1.

The detection circuit SPC is electrically connected to each gate electrode GEp of a plurality of MISFET2Q and each gate electrode GEn of a plurality of MISFET3Q via wiring M1 and wiring M2. Each drain region of the plurality of MISFET2Q and the plurality of MISFET3Q is electrically connected to each gate electrode GEn of the plurality of MISFET1Q via wiring M1 and wiring M2.

For clarity of the drawings, only wiring M1 and wiring M2 used to connect MISFET group 1QA, MISFET group 2QA, MISFET group 3QA, and detection circuit SPC are shown. That is, some of the plurality of wiring M1 and the plurality of wiring M2 are electrically connected to MISFET group 1QA, MISFET group 2QA, MISFET group 3QA, or detection circuit SPC so that MISFET group 1QA, MISFET group 2QA, MISFET group 3QA, or detection circuit SPC is electrically connected to power wiring LVcc1, power wiring LVcc2, ground wiring LVss1, or ground wiring LVss2.

In the examined example, as shown in FIGS. 5 and 6, there was a problem that the signal delay increases as the distance from MISFET group 2QA increases due to the addition of wiring resistance. For example, the wiring path of the MISFET1Q farthest from MISFET group 2QA is approximately the sum of the length of the long side of MISFET group 1QA and half the length of the short side of MISFET group 1QA.

In the first embodiment, as shown in FIG. 7, a group of MISFETs 2QA is provided along the long side of the group of MISFETs 1QA. Therefore, the wiring path of the MISFET 1Q, which is the farthest from the group of MISFETs 2QA, is approximately half the length of the short side of the group of MISFETs 1QA.

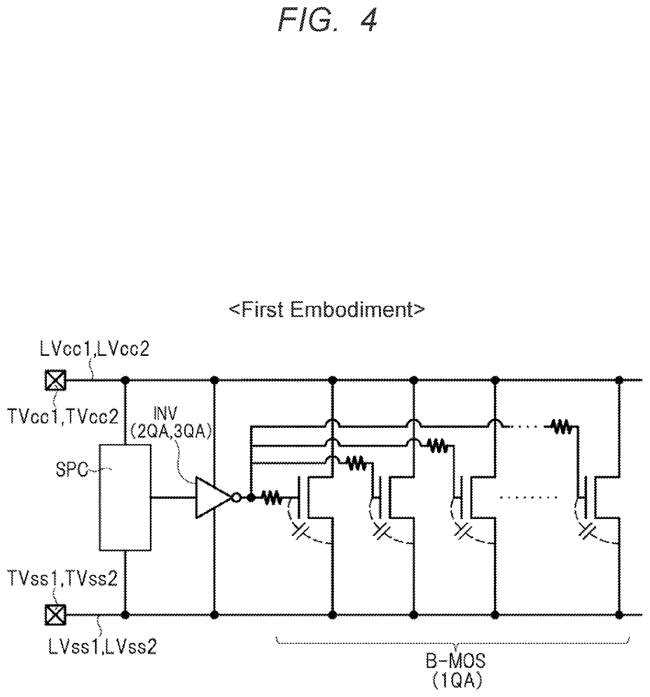

As can be understood by comparing FIGS. 4 and 5, the equivalent circuit of the ESD protection circuit 50 in the first embodiment is the same as that of the examined example of the ESD protection circuit 50, but in the first embodiment and the examined example, the distribution of the wiring resistance differs. In the first embodiment, the wiring resistance between each of the gate electrodes GEn of the plurality of MISFETs 1Q, which are connected in parallel with each other, and the group of MISFETs 2QA is equalized at a low value. Therefore, in the first embodiment, compared to the examined example, the signal delay from the group of MISFETs 2QA to the gate electrode GEn of the MISFET 1Q can be significantly suppressed.

Thus, according to the first embodiment, it is possible to suppress the problem of reduced gate driving force in some of the MISFETs 10 in the group of MISFETs 1QA, and the problem of slower speed in becoming on-state. Therefore, it is possible to improve the clamp performance of the ESD protection circuit 50, and sufficiently protect the plurality of circuits and I/O signal cells IOC provided in the core region CR from the ESD current. This means that the ESD withstand voltage of the semiconductor device 100 can be improved, and it can also be said that higher reliability than conventional can be ensured.

In the first embodiment, the wiring resistance between the group of MISFETs 2QA of the inverter INV and the discharge circuit B-MOS (group of MISFETs 1QA) is reduced, but the wiring resistance between the detection circuit SPC and the group of MISFETs 2QA of the inverter INV slightly increases. However, the number of MISFETs 2Q included in the group of MISFETs 2QA is significantly less than the number of MISFETs 10 included in the group of MISFETs 1QA. Also, the total gate width of the plurality of MISFETs 20 included in the group of MISFETs 2QA is about several tens to a hundred um, which is significantly less than the total gate width of the plurality of MISFETs 1Q included in the group of MISFETs 1QA. Therefore, the total gate capacitance of the group of MISFETs 2QA is small. Hence, the increase in wiring resistance between the detection circuit SPC and the group of MISFETS 2QA does not significantly affect the clamp performance of the ESD protection circuit 50.

On the other hand, the total gate width of the plurality of MISFETs 1Q included in the group of MISFETs 1QA is about several thousand um, and the total gate capacitance of the group of MISFETs 1QA is very large compared to the total gate capacitance of the group of MISFETs 2QA. Therefore, the reduction in wiring resistance between the group of MISFETs 2QA and the group of MISFETs 1QA significantly affects the clamp performance of the ESD protection circuit 50. Therefore, by the first embodiment, it is possible to significantly improve the clamp performance of the ESD protection circuit 50.

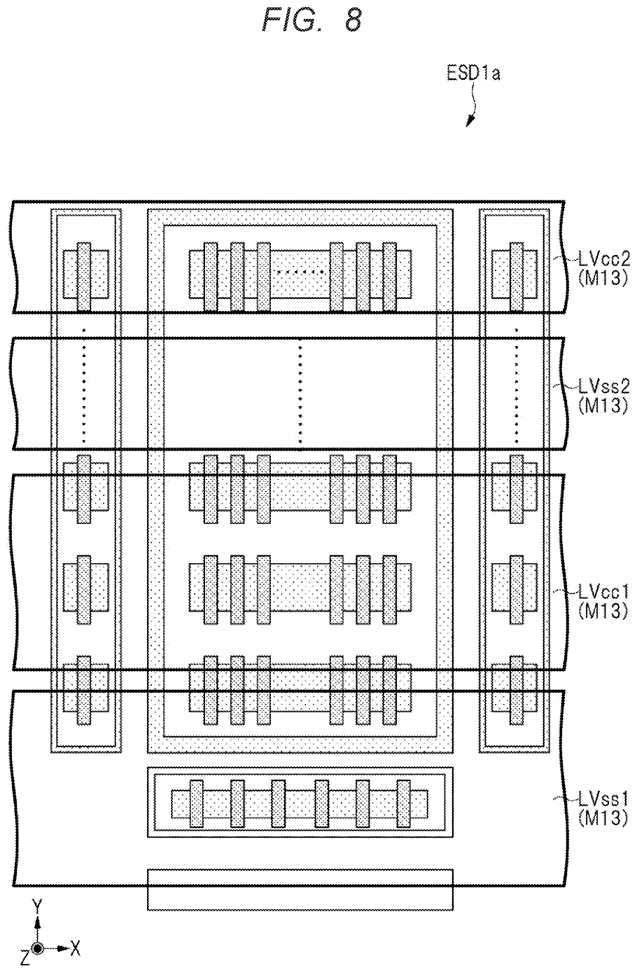

FIG. 8 shows a plan layout of the power wiring LVcc1, power wiring LVcc2, ground wiring LVss1, and ground wiring LVss2 provided above the protection cell ESD1a. Power supply wiring LVcc1, power supply wiring LVcc2, ground wiring LVss1, and ground wiring LVss2 are each a wiring M13 formed in a wiring layer above the wiring layers of wiring M1 and wiring M2 among the multilayer wiring layers.

The protection cell ESD1a is used in the ESD protection circuit 50 for a plurality of circuits provided in the core region CR. Therefore, to discharge quickly with the discharge circuit B-MOS, it is preferable that the wiring path between the discharge circuit B-MOS and the power supply wiring LVcc1 and the ground wiring LVss1 is as short as possible. For this reason, it is preferable that the power supply wiring LVcc1 and the ground wiring LVss1 are arranged to overlap as much as possible with the MISFET group 1QA of the protection cell ESD1a in a plan view.

Therefore, among the two short sides of the MISFET group 1QA, the side opposite to the one adjacent to the MISFET group 2QA is arranged near the power supply wiring LVcc1 and the ground wiring LVss1. Also, the said one short side of the MISFET group 1QA is arranged near the power supply wiring LVcc2 and the ground wiring LVss2.

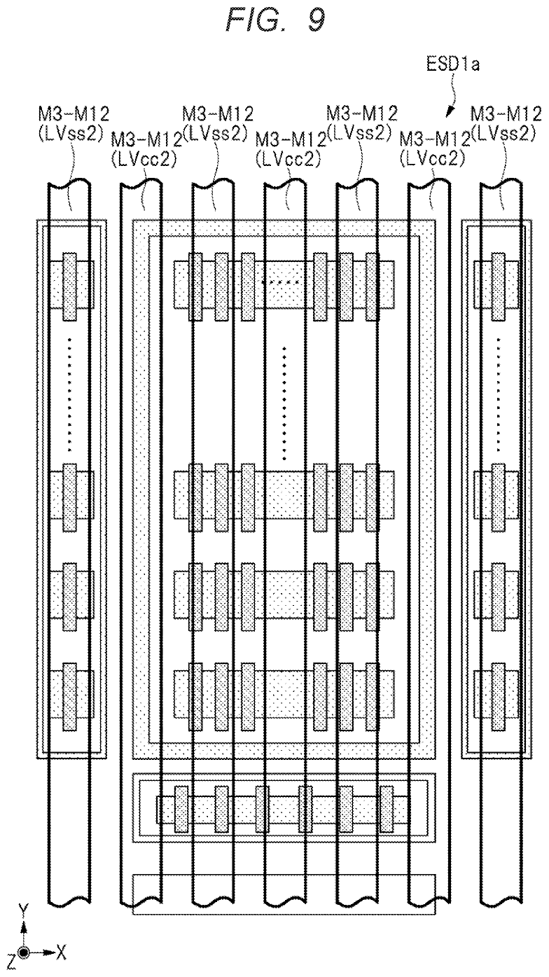

FIG. 9 shows the plan layout of wiring M3 to wiring M12 provided above the protection cell ESD1a. Wiring M3 to wiring M12 are each formed in a wiring layer between wiring M13 and wiring M2 among the multilayer wiring layers.

Wiring M3 to wiring M12 each extend in a direction crossing the extending direction of the power supply wiring LVcc1 and the ground wiring LVss1, which are wiring M13, and are electrically connected to the power supply wiring LVcc1 and the ground wiring LVss1.

As described above, some of the plurality of wiring M1 and the plurality of wiring M2 are electrically connected to the power supply wiring LVcc1 and the ground wiring LVss1 through these wiring M3 to wiring M12. Using such some of the wiring M1 and wiring M2, and wiring M3 to wiring M12, the detection circuit SPC, MISFET group 2QA, MISFET group 3QA, and MISFET group 1QA are each electrically connected to the power supply wiring LVcc1 and the ground wiring LVss1 to electrically short-circuit them.

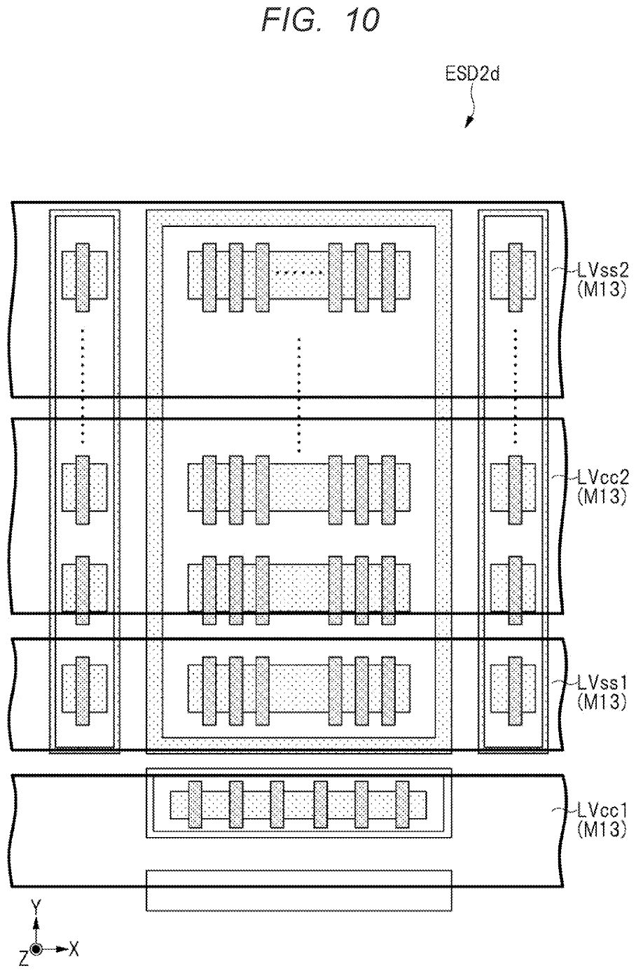

FIG. 10 shows the plan layout of the power supply wiring LVcc1, power supply wiring LVcc2, ground wiring LVss1, and ground wiring LVss2 provided above the protection cell ESD2d.

The protection cell ESD2d is used in the ESD protection circuit 50 for the I/O signal cell IOC. Therefore, to discharge quickly with the discharge circuit B-MOS, it is preferable that the wiring path between the discharge circuit B-MOS and the power supply wiring LVcc2 and the ground wiring LVss2 is as short as possible. For this reason, it is preferable that the power supply wiring LVcc2 and the ground wiring LVss2 are arranged to overlap as much as possible with the MISFET group 1QA of the protection cell ESD2d in a plan view.

Therefore, among the two short sides of the MISFET group 1QA, the other short side opposite to the one adjacent to the MISFET group 2QA is arranged near the power supply wiring LVcc2 and the ground wiring LVss2. Furthermore, the one short side of the MISFET group 1QA is arranged near the power supply wiring LVcc1 and the ground wiring LVss1.

Although not shown, above the protection cell ESD2d, wirings M3 to M12 are formed in the same principle as in FIG. 9. These wirings M3 to M12 extend in a direction crossing the extending direction of the power supply wiring LVcc2 and the ground wiring LVss2, which are the wiring M13, and are electrically connected to the power supply wiring LVcc2 and the ground wiring LVss2. Therefore, in the protection cell ESD2d as well, the detection circuit SPC, MISFET groups 2QA, 3QA, and 1QA are electrically connected to the power supply wiring LVcc2 and the ground wiring LVss2 through wirings M1 to M12 so as to electrically short-circuit the power supply wiring LVcc2 and the ground wiring LVss2.

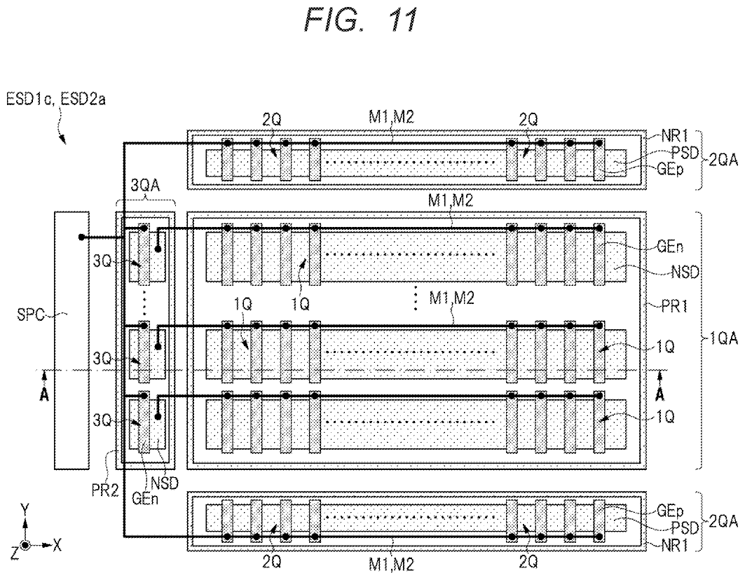

FIG. 11 shows the planar layout of the protection cell ESD1c and the protection cell ESD2a. The planar layout of the protection cell ESD1d is similar to that of the protection cell ESD1c when viewed in plain view rotated 180 degrees. The planar layout of the protection cell ESD2b is similar to that of the protection cell ESD2a when viewed in plain view rotated 180 degrees.

As shown in FIG. 11, in the protection cells ESD1c and ESD2a, the connection relationship of the MISFET groups 1QA, 2QA, 3QA, and the detection circuit SPC is the same as in the protection cells ESD1a and ESD2d. Furthermore, in the protection cells ESD1c and ESD2a, the arrangement relationship of the MISFET groups 1QA, 2QA, 3QA, and the detection circuit SPC is the same as in the protection cells ESD1a and ESD2d.

That is, in the protection cells ESD1c and ESD2a as well, the MISFET group 1QA is adjacent to a pair of MISFET groups 2QA and is provided between the pair of MISFET groups 2QA. Moreover, in the direction from the core region CR towards the side 10c, the MISFET group 1QA, the MISFET group 3QA, and the detection circuit SPC are provided in sequence. In other words, the MISFET group 1QA is provided between the core region CR and the MISFET group 3QA. The MISFET group 3QA is provided between the MISFET group 1QA and the detection circuit SPC.

Furthermore, in the protection cells ESD1c and ESD2a as well, the planar arrangement shape of the MISFET group 1QA forms a rectangular shape. A pair of MISFET groups 2QA are provided along the long side of the MISFET group 1QA, and the MISFET group 3QA is provided along the short side of the MISFET group 1QA. The detection circuit SPC is provided along the short side of the MISFET group 1QA through the MISFET group 3QA.

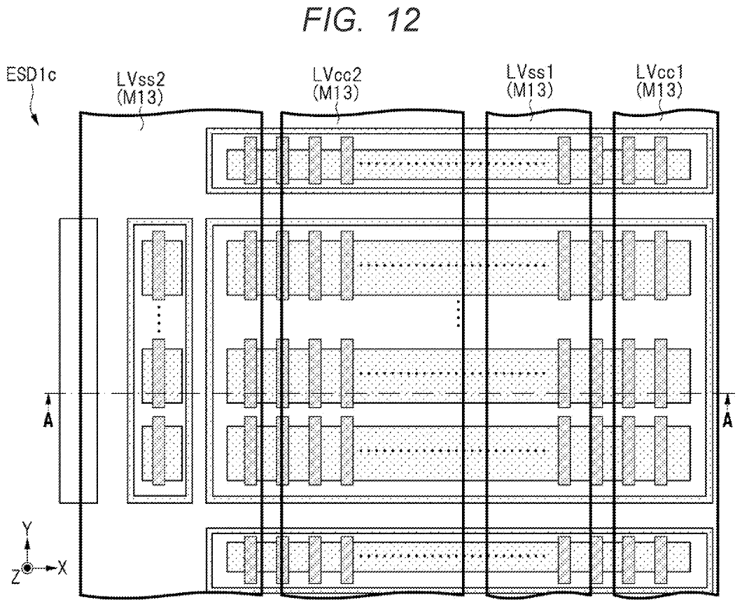

FIG. 12 shows a plan layout of power wiring LVcc1, power wiring LVcc2, ground wiring LVss1, and ground wiring LVss2 provided above the protective cell ESD1c.

In order to discharge quickly with the discharge circuit B-MOS, it is preferable that the wiring path between the discharge circuit B-MOS and the power wiring LVcc1 and ground wiring LVss1 is as short as possible. Therefore, it is preferable that the power wiring LVcc1 and ground wiring LVss1 are arranged so as to overlap as much as possible with the MISFET group 1QA of the protective cell ESD1c in a plan view.

Accordingly, among the two short sides of the MISFET group 1QA, the side opposite to the one adjacent to the MISFET group 2QA is arranged near the power wiring LVcc1 and ground wiring LVss1. Also, the aforementioned one short side of the MISFET group 1QA is arranged near the power wiring LVcc2 and ground wiring LVss2.

Although not shown, above the protective cell ESD1c, wirings M3 to M12 are formed in the same spirit as FIG. 9. These wirings M3 to M12 extend in a direction crossing the extending direction of the power wiring LVcc1 and ground wiring LVss1, which is wiring M13, and are electrically connected to the power wiring LVcc1 and ground wiring LVss1. Therefore, in the protective cell ESD1c as well, the detection circuit SPC, MISFET groups 2QA, 3QA, and 1QA are electrically connected to the power wiring LVcc1 and ground wiring LVss1 through wirings M1 to M12 so as to electrically short-circuit the power wiring LVcc1 and ground wiring LVss1.

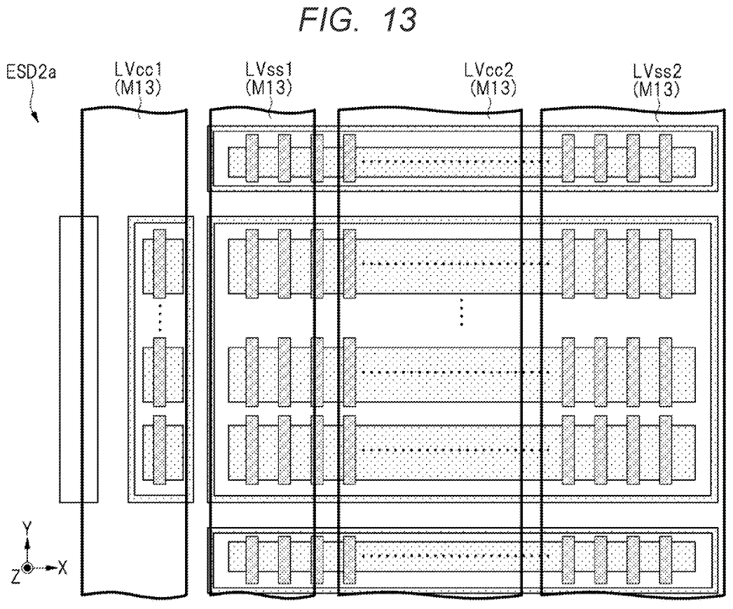

FIG. 13 shows a plan layout of power wiring LVcc1, power wiring LVcc2, ground wiring LVss1, and ground wiring LVss2 provided above the protective cell ESD2a.

In order to discharge quickly with the discharge circuit B-MOS, it is preferable that the wiring path between the discharge circuit B-MOS and the power wiring LVcc2 and ground wiring LVss2 is as short as possible. Therefore, it is preferable that the power wiring LVcc2 and ground wiring LVss2 are arranged so as to overlap as much as possible with the MISFET group 1QA of the protective cell ESD2a in a plan view.

Accordingly, among the two short sides of the MISFET group 1QA, the side opposite to the one adjacent to the MISFET group 2QA is arranged near the power wiring LVcc2 and ground wiring LVss2. Also, the aforementioned one short side of the MISFET group 1QA is arranged near the power wiring LVcc1 and ground wiring LVss1.

### Cross-Sectional Structure of the Protective Cell

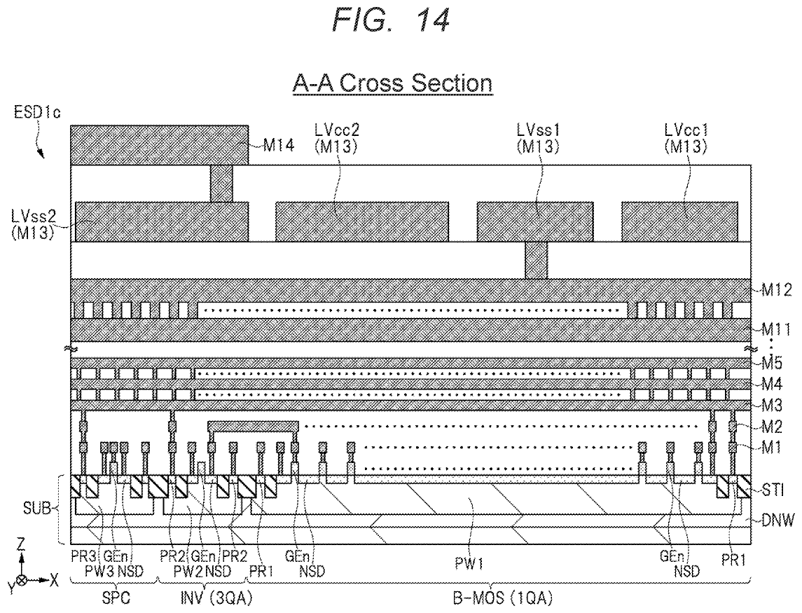

FIG. 14 is a cross-sectional view along line A-A shown in FIGS. 11 and 12. As an example of the cross-sectional structure of protective cells ESD1 and ESD2, the cross-sectional structure of the protective cell ESD1c is described.

As illustrated in FIG. 14, a semiconductor device 100 comprises a semiconductor substrate SUB, a plurality of transistors, and a multilayer wiring layer formed on the semiconductor substrate SUB.

The semiconductor substrate SUB has an upper surface and a lower surface and is made of p-type silicon. In the semiconductor substrate SUB, an element isolation part STI is formed. The element isolation part STI includes a groove formed in the semiconductor substrate SUB to reach a predetermined depth from the upper surface of the semiconductor substrate SUB, and an insulating film embedded inside the groove. The insulating film is, for example, an oxide silicon film.

In the semiconductor substrate SUB, an n-type well region DNW is formed. The semiconductor substrate SUB is electrically connected to a ground wiring LVss1. The well region DNW serves to electrically isolate the ground wiring LVss1 and the ground wiring LVss2. In the case where a region where a protective cell ESD1 is formed is used as a region for electrically connecting the ground wiring LVss1 to the semiconductor substrate SUB, the well region DNW is not formed in the region where the protective cell ESD1 is formed.

In the well region DNW, p-type well regions PW1, PW2, and PW3 are formed. On the well regions PW1, PW2, and PW3, gate electrodes GEn is formed through gate insulating films, respectively. The gate electrodes GEn is, for example, n-type polycrystalline silicon films.

In the well regions PW1, PW2, and PW3, n-type impurity regions NSD are formed, respectively. Also, in the well region PW1, a p-type impurity region PRI is formed, in the well region PW2, a p-type impurity region PR2 is formed, and in the well region PW3, a p-type impurity region PR3 is formed.

A MISFET1Q has a gate insulating film and a gate electrode GEn formed on the well region PW1 and has an impurity region NSD formed in the well region PW1 as a source region or a drain region. In the well region PW1, a portion located between the source region and the drain region and covered by the gate electrode GEn functions as a channel region of the MISFET1Q. A ground potential is supplied to the well region PW1 through an impurity region PR1 electrically connected to the ground wiring LVss1 or the ground wiring LVss2.

As described in FIGS. 7 and 11, the planar arrangement shape of the MISFET group 1QA forms a rectangular shape. In other words, the planar shape of the well region PW1 where the MISFET group 1QA is formed is rectangular. Further, the area surrounded by the impurity region PRI in a plan view is the area where the MISFET group 1QA is arranged, and it is rectangular.

MISFET3Q comprises a gate insulating film, and a gate electrode GEn formed on the well region PW2 and has an impurity region NSD formed in the well region PW2 as a source region or a drain region. In the well region PW2, the portion located between the source region and the drain region, and covered by the gate electrode GEn, functions as the channel region of MISFET2Q. A ground potential is supplied to the well region PW2 through an impurity region PR2 that is electrically connected to either the ground wiring LVss1 or the ground wiring LVss2.

The integration circuit of the detection circuit SPC is mainly composed of capacitive elements and resistive elements. These capacitive elements and resistive elements can be configured by appropriately combining the well region PW3, the gate insulating film, and the gate electrode GEn formed on the well region PW3, and the impurity region NSD formed in the well region PW3. The resistive elements may be constituted by a barrier metal film included in the wiring of a damascene structure or a dual damascene structure described later.

Although not shown in FIG. 14, the following description is about the MISFET group 2QA (MISFET2Q) in FIG. 11. An n-type well region is formed in the well region DNW where the MISFET group 2QA is formed. A gate electrode GEp is formed on the n-type well region through a gate insulating film. In the n-type well region, a p-type impurity region PSD and an n-type impurity region NR1 are formed. MISFET2Q has a gate insulating film and a gate electrode GEp formed on the n-type well region and has the impurity region PSD as a source region or a drain region. In the n-type well region, the portion located between the source region and the drain region, and covered by the gate electrode GEp, functions as the channel region of MISFET2Q. A power supply potential is supplied to the n-type well region through an impurity region NR1 that is electrically connected to either the power supply wiring LVcc1 or the power supply wiring LVcc2.

A multilayer wiring layer is formed on the semiconductor substrate SUB and has a plurality of wiring layers. In the example of FIG. 14, the multilayer wiring layer is constituted by the first wiring layer to the fourteenth wiring layer. In the first wiring layer to the fourteenth wiring layer, wirings M1 to M14 are formed, respectively. The first wiring layer to the fifth wiring layer are local wiring layers, the sixth wiring layer to the twelfth wiring layer are semi-global wiring layers, and the thirteenth wiring layer and the fourteenth wiring layer are global wiring layers.

The thickness of each of the wirings M13 and M14 is thicker than the thickness of each of the wirings M6 to M12, and the line width of each of the wirings M13 and M14 is wider than the line width of each of the wirings M6 to M12. The thickness of each of the wirings M6 to M12 is thicker than the thickness of each of the wirings M1 to M5, and the line width of each of the wirings M6 to M12 is wider than the line width of each of the wirings M1 to M5.

Wirings M1 to M14 are each a wiring with a damascene structure or a dual damascene structure, comprising a barrier metal film including, for example, a tantalum film and a tantalum nitride film, and a copper film formed on the barrier metal film and having a thickness greater than that of the barrier metal film.

Note that the power terminal TVcc1, the ground wiring LVss1, the power wiring LVcc2, and the ground terminal TVss2 shown in FIGS. 3, 4, and 5 are constituted by a part of the wiring formed on the upper layer of the wiring M14 (not shown). The wiring formed on the upper layer of the wiring M14 is primarily formed of a patterned aluminum alloy film.

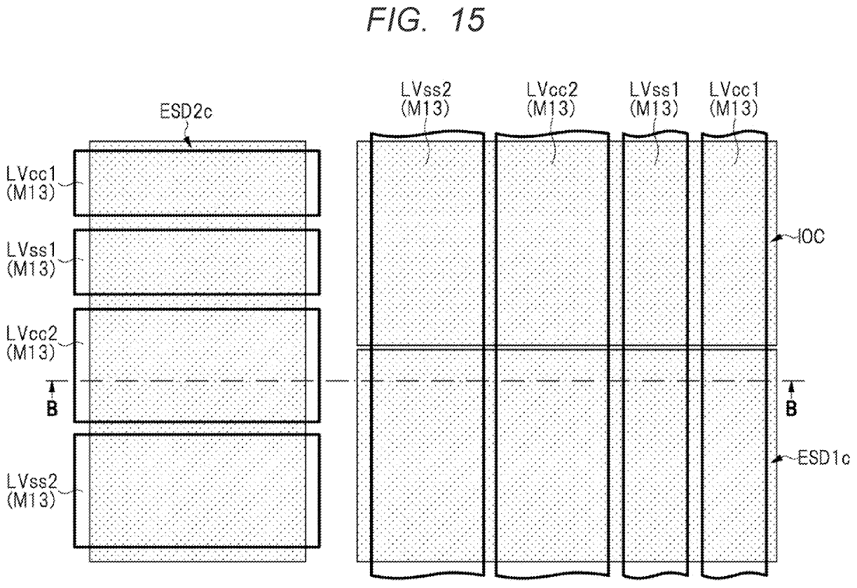

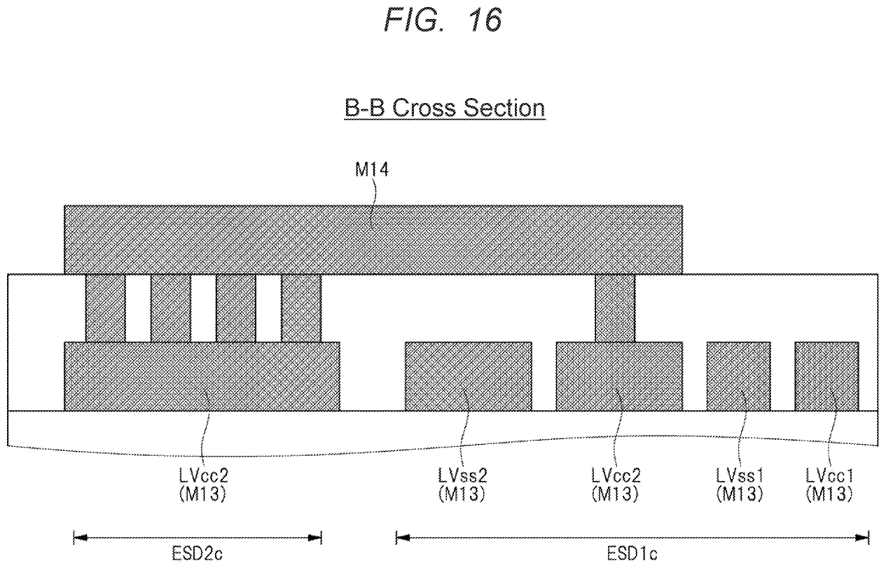

Hereinafter, the connection relationship between the power wiring LVcc1, the power wiring LVcc2, the ground wiring LVss1, and the ground wiring LVss2, which circulate above the plurality of protection cells ESD1 and the plurality of I/O signal cells IOC, and the power wiring LVcc1, the power wiring LVcc2, the ground wiring LVss1, and the ground wiring LVss2 provided above the protection cell ESD2, respectively, will be described using FIGS. 15 and 16.

Here, the area above the protection cells ESD1c and ESD2c is exemplified. FIG. 16 is a cross-sectional view along the line B-B shown in FIG. 15.

As shown in FIG. 16, the power wiring LVcc2 located above the protection cell ESD1c is electrically connected to the power wiring LVcc2 located above the protection cell ESD2c by the wiring M14. In addition, similar to the power supply wiring LVcc1 and the ground wiring LVss1, the wiring M14 enables a connection from above the protection cell ESD1c or the I/O signal cell IOC to above the protection cell ESD2c.

Furthermore, above the protection cell ESD1c or the I/O signal cell IOC, the ground wiring LVss2 is positioned on the outer periphery compared to the power supply wiring LVcc1, the ground wiring LVss1, and the power supply wiring LVcc2. There is no other wiring present between the ground wiring LVss2 positioned above the protection cell ESD1c or the I/O signal cell IOC and the ground wiring LVss2 positioned above the protection cell ESD2c. Therefore, these ground wirings LVss2 may be integrated or may be electrically connected via the wiring M14.

In the first embodiment, although a case where the multilayer wiring layer is composed of the first wiring layer to the fourteenth wiring layer is exemplified, the number of wiring layers in the multilayer wiring layer is not limited to fourteen and may be more or less than fourteen.

### Detailed Structure of Each MISFET

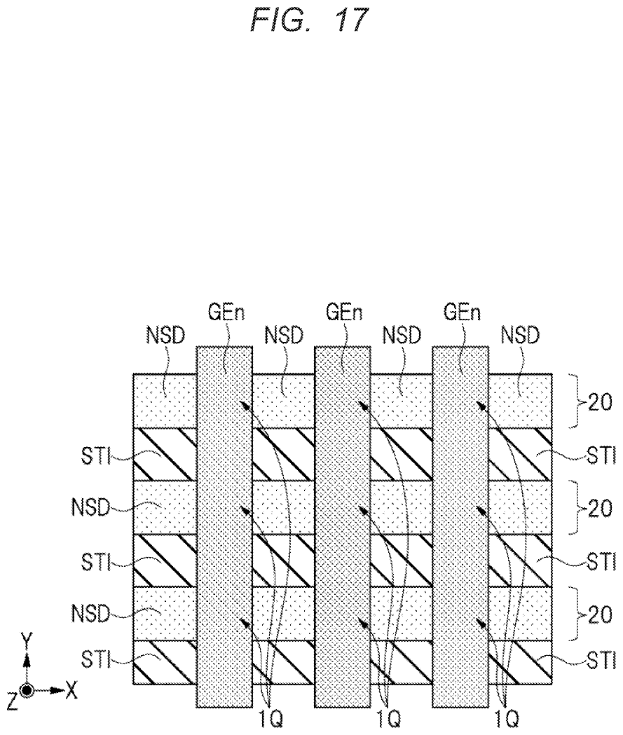

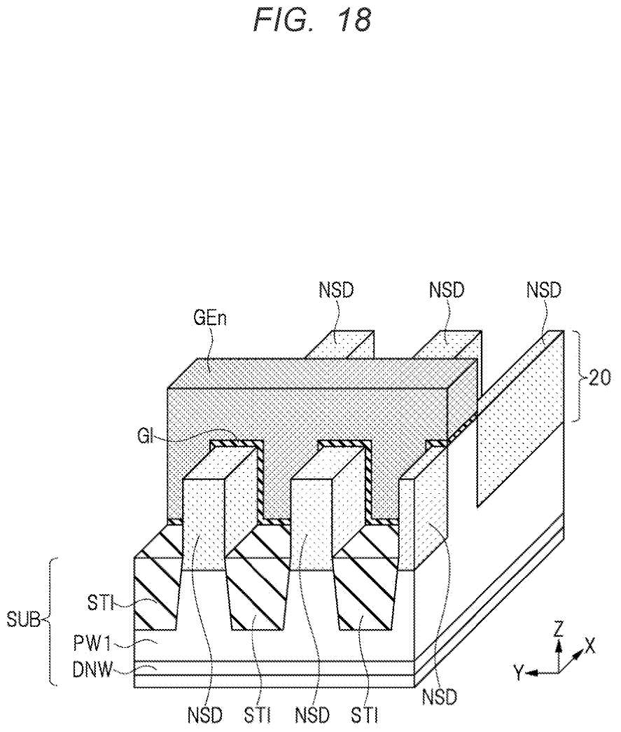

Hereinafter, using FIGS. 17 and 18, the detailed structure of a plurality of MISFETs included in the semiconductor device 100, such as MISFET1Q, MISFET2Q, MISFET3Q, MISFETs provided in the core region CR, and MISFETs provided in the I/O signal cell IOC, will be described.

In the first embodiment, the channel region of each of the plurality of MISFETs included in the semiconductor device 100 is three-dimensionally covered by the gate electrode of each of the plurality of MISFETs. Such MISFETs can apply a FIN-FET structure, or a GAA (Gate All Around) structure using nanowires or nanosheets.

In FIGS. 17 and 18, a case where the plurality of MISFETs included in the semiconductor device 100 have a FIN-FET structure is described. Here, a plurality of MISFET1Qs included in the MISFET group 1QA are exemplified.

As shown in FIGS. 17 and 18, a plurality of protrusions 20, which are part of the semiconductor substrate SUB, are provided on the semiconductor substrate SUB. The a plurality of protrusions 20 extend in the X direction and are separated from each other in the Y direction. On the semiconductor substrate SUB positioned between the plurality of protrusions 20, element separation parts STI are formed respectively. In other words, the space between the plurality of protrusions 20 corresponds to grooves formed in the semiconductor substrate SUB, and inside these grooves, the element separation parts STI are formed. The upper surface position of the element separation part STI is lower than the upper surface position of the protrusion 20.

The gate electrode GEn extends in the Y direction and is formed to cover at least one of the upper surfaces and both side surfaces of the plurality of protrusions 20. The gate insulation film GI is formed between the gate electrode GEn and the protrusion 20. The well region PW1 is formed in the semiconductor substrate SUB, including the protrusion 20. The impurity region NSD is formed in the protrusion 20 (within the well region PW1) exposed from the gate electrode GEn.

In the case of a FIN-FET structure, the well region PW1, which is covered by the gate electrode GEn and positioned between the two impurity regions NSD that become the source region or the drain region, becomes the channel region of the MISFET1Q.

Since the MISFET has a three-dimensional structure like a FIN-FET structure, it is possible to place more MISFETs in the same planar area compared to a planar structure, and secure more drive current. Therefore, the miniaturization of the semiconductor device 100 can be promoted.

On the other hand, for the acceleration of MISFET, the thinning of the gate insulating film is being promoted. In the case of MISFETs provided in the protection cell ESD1 and the core region CR, the thickness of the gate insulating film GI is, for example, 1 nm or more and 4 nm or less. In the case of MISFETs provided in the protection cell ESD2 and the I/O signal cell IOC, the thickness of the gate insulating film GI is thicker than in the case of the protection cell ESD1, for example, 3 nm or more and 6 nm or less.

Moreover, the gate insulating film GI is, for example, a silicon oxide film or a laminated film of a silicon oxide film and a high dielectric constant film. The above high dielectric constant film is an insulating film having a higher dielectric constant than a silicon nitride film, for example, a hafnium oxide film (HfO₂ film) or a hafnium silicate film (HfSiO film). With the thinning and high dielectric constant of the gate insulating film, the gate capacitance tends to increase. With the increase in gate capacitance, signal delay is likely to occur between the MISFET group 2QA and the MISFET group 1QA (refer to FIG. 4). However, by adopting the protection cell ESD1 and the protection cell ESD2 of the first embodiment, it is possible to significantly reduce the wiring resistance and greatly suppress the signal delay, thus suitably addressing the thinning of the gate insulating film.

Furthermore, in the FIN-FET structure, manufacturing process constraints arise in forming the protrusions 20, making it difficult to form a plurality of protrusions 20 extending in different directions. The gate electrode needs to extend in a direction crossing the extending direction of the protrusion 20 in order to cover the upper surface and both side surfaces of the protrusion 20. Therefore, as shown in FIGS. 7 and 11, even if the orientation of the protection cell ESD1 and the protection cell ESD2 differs, the extending direction of the gate electrode is fixed in the Y direction. In the first embodiment, even if the extending direction of the gate electrode is fixed, it can cope with the suppression of signal delay.

As described above, the first embodiment has been explained in the case where a plurality of MISFETs included in the semiconductor device 100 have a three-dimensional structure like a FIN-FET structure. However, even if a plurality of MISFETs have a planar structure, by using the protection cell ESD1 and the protection cell ESD2 of the first embodiment, it is possible to improve the clamping performance of the ESD protection circuit 50 and enhance the reliability of the semiconductor device 100.

### Second Embodiment

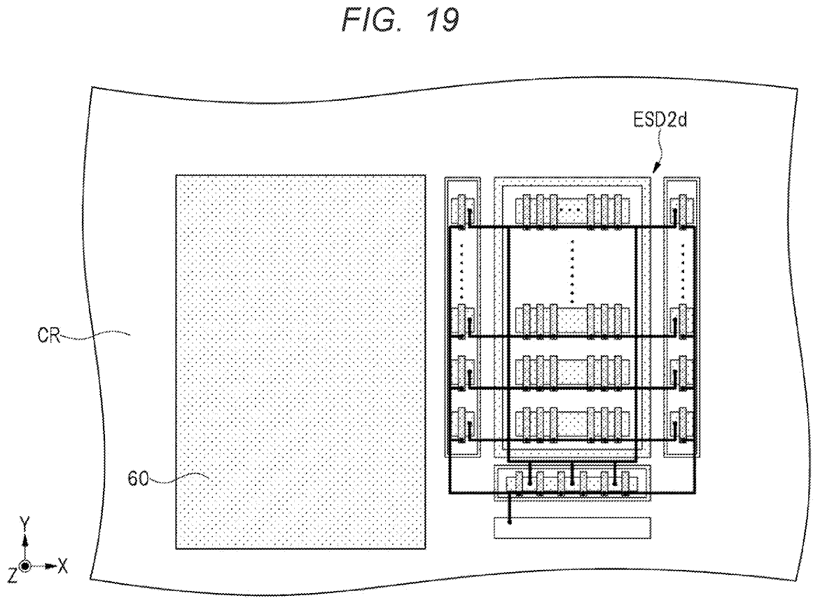

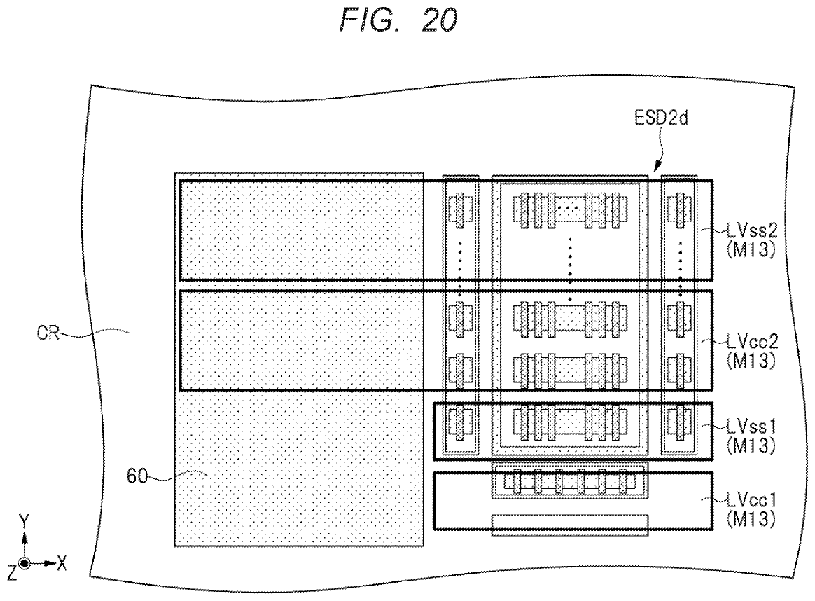

Hereinafter, the semiconductor device in the second embodiment will be described using FIGS. 19 and 20. Note that, in the following description, mainly the differences from the first embodiment will be explained, and the points overlapping with the first embodiment will be omitted.

In the first embodiment, protection cells ESD1 and ESD2 are provided in the outer peripheral region OR. In the second embodiment, a case where either protection cell ESD1 or protection cell ESD2 is provided in the core region CR will be described.

As shown in FIG. 19, although a plurality of circuits are provided in the core region CR, these a plurality of circuits include analog IP60. The specific example of analog IP60 is as previously described. Since analog IP60 is susceptible to noise, to avoid noise propagation from the circuit area where the common semiconductor chip uses the power supply voltage and the ground voltage, analog IP60 often has a dedicated power supply voltage and ground voltage. Therefore, for analog IP60 shown in FIG. 19, unlike other circuits, the power potential and ground potential are supplied from the power wiring and ground wiring provided exclusively for analog IP60. Depending on the specifications of analog IP60, it may be possible to use power wiring LVcc1 and ground wiring LVss1, or power wiring LVcc2 and ground wiring LVss2, for supplying the power potential and ground potential.

In the second embodiment, using power wiring LVcc2 and ground wiring LVss2 to supply the power potential and ground potential to analog IP60, and using protection cell ESD2d as the ESD protection circuit 50 is exemplified.

As shown in FIGS. 19 and 20, protection cell ESD2d is provided adjacent to analog IP60. The power wiring LVcc2 and ground wiring LVss2 are formed in the 13th wiring layer so as to overlap with analog IP60 and protection cell ESD2d in plain view. Although not shown, the power wiring LVcc2 and ground wiring LVss2 are electrically connected to analog IP60 and protection cell ESD2d through wirings M1 to M12. The power terminal TVcc2 and ground terminal TVss2 for analog IP60 are constituted by a part of the wiring formed on the upper layer of wiring M14, which is formed directly above the power wiring LVcc2 and ground wiring LVss2 shown in FIG. 20.

Thus, in the second embodiment, analog IP60 can be protected from ESD current by the protection cell ESD2d provided exclusively for analog IP60.

Depending on the planar layout shape of analog IP60, or the space around analog IP60, it may also be possible to use protection cell ESD2a, protection cell ESD2b, or protection cell ESD2c instead of protection cell ESD2d. Also, when using power wiring LVcc1 and ground wiring LVss1 to supply the power potential and ground potential to analog IP60, it may be possible to use protection cell ESD1a, protection cell ESD1b, protection cell ESD2c, or protection cell ESD1d.

As described above, the present invention has been specifically described based on the embodiments, but the present 10 invention is not limited to these embodiments and can be variously modified without departing from the spirit thereof.

What is claimed is:

1. A semiconductor device comprising:
a core region provided with a plurality of circuits;
a peripheral region surrounding the core region in a plan view;
a protection cell provided in the peripheral region and constituting an ESD protection circuit;
a power supply wiring for supplying a power potential; and
a ground wiring for supplying a ground potential,
wherein the protection cell includes a first MISFET group composed of a plurality of first MISFETs of a first conductivity type, and a pair of second MISFET groups composed of a plurality of second MISFETs of a second conductivity type opposite to the first conductivity type,
wherein the first MISFET group and the pair of the second MISFET groups are electrically connected to the power supply wiring and the ground wiring, respectively, to electrically short-circuit them,
wherein the pair of the second MISFET groups outputs a signal to turn on the plurality of the first MISFETs to each of the first gate electrodes of the plurality of the first MISFETs, and
wherein the first MISFET group is provided between the pair of the second MISFET groups.

2. The semiconductor device according to claim 1,
wherein the protection cell further includes a third MISFET group composed of a plurality of third MISFETs of the first conductivity type,
wherein the third MISFET group is electrically connected to the power supply wiring and the ground wiring, respectively, to electrically short-circuit them,
wherein the third MISFET group outputs a signal to turn off the plurality of the first MISFETs to each of the first gate electrodes of the plurality of the first MISFETs, and
wherein the first MISFET group is provided between the core region and the third MISFET group.

3. The semiconductor device according to claim 2,
wherein the arrangement shape of the first MISFET group in a plan view forms a rectangular shape,
wherein the pair of the second MISFET groups is provided along the long sides of the first MISFET group, and
wherein the third MISFET group is provided along the short sides of the first MISFET group.

4. The semiconductor device according to claim 3,
wherein the protection cell further includes a detection circuit capable of detecting an ESD current to the power supply wiring,
wherein the detection circuit is electrically connected to the power supply wiring and the ground wiring, respectively, to electrically short-circuit them,
wherein the detection circuit is electrically connected to each of the second gate electrodes of the plurality of the second MISFETs, and to each of the third gate electrodes of the plurality of the third MISFETs, and
wherein the detection circuit is provided along the short sides of the first MISFET group.

5. The semiconductor device according to claim 4,
wherein the third MISFET group is provided between the first MISFET group and the detection circuit, and
wherein the detection circuit is provided along the short sides of the first MISFET group through the third MISFET group.

6. The semiconductor device according to claim 5, further comprising:
a plurality of first wirings used for connecting the first MISFET group, the second MISFET group, the third MISFET group, and the detection circuit,
wherein the power wiring and the ground wiring are formed in a wiring layer above the plurality of the first wirings, and are provided in the outer peripheral area to overlap with the protection cell in a plan view, and
wherein the thickness of each of the power wiring and the ground wiring is thicker than the thickness of each of the plurality of the first wirings.

7. The semiconductor device according to claim 1,
wherein each of the first gate electrodes of the plurality of the first MISFETs extends in a first direction in a plan view.

8. The semiconductor device according to claim 7,
Wherein each channel region of the plurality of the first MISFETs is three-dimensionally covered by each of the first gate electrodes of the plurality of the first MISFETs.

9. The semiconductor device according to claim 8, further comprising:
a semiconductor substrate;
a plurality of protrusions which are part of the semiconductor substrate and extend in a second direction crossing the first direction in a plan view and are separated from each other in the first direction; and
an element isolation part formed on the semiconductor substrate between the plurality of protrusions,
wherein the position of the upper surface of the element isolation part is lower than the position of the upper surface of the protrusions, and
wherein the first gate electrode is formed to cover at least one of the upper surface and both side surfaces of the plurality of protrusions.

10. The semiconductor device according to claim 7, further comprising:
a first side along the first direction;
a second side along the second direction crossing the first direction in a plan view; and
a plurality of protection cells,
wherein the first side and the second side constitute the outer edge of the outer peripheral area,
wherein the plurality of protection cells include a first protection cell provided between the first side and the core area, and a second protection cell provided between the second side and the core area,
wherein the arrangement shape of the first MISFET group in a plan view forms a rectangular shape,
wherein the long side of the first MISFET group of the first protection cell follows the second direction, and
wherein the long side of the first MISFET group of the second protection cell follows the first direction.

11. The semiconductor device according to claim 10,
wherein a plurality of the first protection cells is provided between the first side and the core area, and
wherein a plurality of the second protection cells are provided between the second side and the core area.

12. The semiconductor device according to claim 10, further comprising:
a plurality of the power supply wirings; and
a plurality of the ground wirings,
wherein among the plurality of the power supply wirings, a first power supply wiring supplies a power supply potential to the plurality of circuits provided in the core region,
wherein among the plurality of the ground wirings, a first ground wiring supplies a ground potential to the plurality of circuits provided in the core region,
wherein the first group of MISFETs of the first protection cell and a pair of the second group of MISFETs are electrically connected to the first power supply wiring and the first ground wiring, respectively, so as to electrically short-circuit them, and
wherein the first group of MISFETs of the second protection cell and a pair of the second group of MISFETs are electrically connected to the first power supply wiring and the first ground wiring, respectively, so as to electrically short-circuit them.

13. The semiconductor device according to claim 12, further comprising:
a plurality of I/O signal cells provided in the peripheral region,
wherein the plurality of protection cells further include a third protection cell provided between the first side and the first protection cell, and a fourth protection cell provided between the second side and the second protection cell,
wherein the long side of the first group of MISFETs of the third protection cell is along the first direction,
wherein the long side of the first group of MISFETs of the fourth protection cell is along the second direction,
wherein among the plurality of the power supply wirings, a second power supply wiring supplies a power supply potential to the plurality of the I/O signal cells,
wherein among the plurality of the ground wirings, a second ground wiring supplies a ground potential to the plurality of the I/O signal cells,
wherein the third protection cell's first group of MISFETs and a pair of the second group of MISFETs are electrically connected to the second power supply wiring and the second ground wiring, respectively, so as to electrically short-circuit them, and
wherein the fourth protection cell's first group of MISFETs and a pair of the second group of MISFETs are electrically connected to the second power supply wiring and the second ground wiring, respectively, so as to electrically short-circuit them.

14. The semiconductor device according to claim 13,
wherein the thickness of the gate insulating film of each of the plurality of the first MISFETs and the plurality of the second MISFETs included in the third protection cell and the fourth protection cell is thicker than the thickness of the gate insulating film of each of the plurality of the first MISFETs and the plurality of the second MISFETs included in the first protection cell and the second protection cell.

15. The semiconductor device according to claim 7, further comprising:
a first side along a first direction;
a second side along a second direction intersecting the first direction in a plan view;
a plurality of protective cells;
a first I/O signal cell provided in the peripheral region and between the first side and the core region; and
a second I/O signal cell provided in the peripheral region and between the second side and the core region,
wherein the first and second sides constitute the outer edge of the peripheral region,
wherein the plurality of protective cells include a third protective cell provided between the first side and the first I/O signal cell, and a fourth protective cell provided between the second side and the second I/O signal cell,
wherein the layout of the first MISFET group in a plan view forms a rectangular shape,
wherein the long side of the first MISFET group of the third protective cell is along the first direction, and
wherein the long side of the first MISFET group of the fourth protective cell is along the second direction.

16. The semiconductor device according to claim 15, further comprising:
a plurality of power supply wirings; and
a plurality of ground wirings,
wherein the second power wiring among the plurality of power wirings supplies power potential to the first I/O signal cell and the second I/O signal cell,
wherein the second ground wiring among the plurality of ground wirings supplies ground potential to the first I/O signal cell and the second I/O signal cell,
wherein the first MISFET group of the third protective cell and the pair of the second MISFET groups are electrically connected to the second power wiring and the second ground wiring, respectively, to electrically short-circuit them, and
wherein the first MISFET group of the fourth protective cell and the pair of the second MISFET groups are electrically connected to the second power wiring and the second ground wiring, respectively, to electrically short-circuit them.

17. A semiconductor device comprising:
an analog IP;
a protective cell provided adjacent to the analog IP and constituting an ESD protection circuit;
a power supply wiring for supplying power potential to the analog IP; and
a ground wiring for supplying ground potential to the analog IP,
wherein the protective cell has a first MISFET group composed of a plurality of first-conductivity-type MISFETs, and a pair of second MISFET groups composed of a plurality of second-conductivity-type MISFETs opposite to the first conductivity type,
wherein the first MISFET group and the pair of the second MISFET groups are electrically connected to the power supply wiring and the ground wiring, respectively, to electrically short-circuit them,
wherein the pair of the second MISFET groups outputs a signal to each first gate electrode of the plurality of first MISFETs to turn on the plurality of first MISFETs, and
wherein the first MISFET group is provided between the pair of the second MISFET groups.

18. The semiconductor device according to claim 17,
wherein the protection cell further comprises a third MISFET group constituted by a plurality of third MISFETs of the first conductivity type,
wherein the third MISFET group is electrically connected to the power supply line and the ground line so as to electrically short-circuit them,
wherein the third MISFET group outputs a signal to turn off the plurality of the first MISFETs to each of the first gate electrodes of the plurality of the first MISFETs,
wherein the arrangement shape of the first MISFET group in plain view forms a rectangular shape,
wherein a pair of the second MISFET groups is provided along the long side of the first MISFET group, and
wherein the third MISFET group is provided along the short side of the first MISFET group.

19. The semiconductor device according to claim 18,
wherein the protection cell further comprises a detection circuit capable of detecting ESD current to the power supply line,
wherein the detection circuit is electrically connected to the power supply line and the ground line so as to electrically short-circuit them,
wherein the detection circuit is electrically connected to each of the second gate electrodes of the plurality of the second MISFETs, and to each h of the third gate electrodes of the plurality of the third MISFETs, and
wherein the detection circuit is provided along the short side of the first MISFET group.

20. The semiconductor device according to claim 19, further comprising:
a plurality of first wirings used to connect the first MISFET group, the second MISFET group, the third MISFET group, and the detection circuit,
wherein the power supply line and the ground line are formed in a wiring layer above the plurality of the first wirings in plain view to overlap with the analog IP and the protection cell, and
wherein the thickness of each of the power supply line and the ground line is thicker than the thickness of each of the plurality of the first wirings.
